(19) United States
(12) Patent Application Publication
(10) Pub. No.: US 2025/0376785 A1
(43) Pub. Date: Dec. 11, 2025

(54) QUARTZ GLASS CRUCIBLE FOR SINGLE-CRYSTAL SILICON PULLING AND METHOD FOR PRODUCING SINGLE-CRYSTAL SILICON USING SAME

(71) Applicant: SUMCO Corporation, Tokyo (JP)

(72) Inventors: Ken KITAHARA, Akita (JP); Hiroshi KISHI, Akita (JP); Eriko KITAHARA, Akita (JP); Kouta HASEBE, Akita (JP); Hideki FUJIWARA, Tokyo (JP)

(73) Assignee: SUMCO Corporation, Tokyo (JP)

(21) Appl. No.: 19/100,297

(22) PCT Filed: Aug. 3, 2023
(86) PCT No.: PCT/JP2023/028389

§ 371 Date: Jan. 31, 2025

(30) Foreign Application Priority Data
Aug. 24, 2022 (JP) 2022-133512

(51) Int. Cl. C30B 15/10; C30B 29/06; C30B 35/00

(52) U.S. Cl. CPC C30B 15/10; C30B 29/06; C30B 35/002

(57) ABSTRACT

A quartz glass crucible includes a crucible base body consisting of silica glass and a crystallization accelerator-containing coating film formed on an inner surface of the crucible base body. A concentration of Fe contained in a first depth region of the crystallization accelerator-containing coating film of 0.5 mm or less from an inner surface of the crucible base body is higher than a concentration of Al contained in the first depth region of the crystallization accelerator-containing coating film.

### TECHNICAL FIELD

The present invention relates to a quartz glass crucible used for pulling up a silicon single crystal by a Czochralski method (CZ method) and a manufacturing method thereof. In addition, the present invention relates to a manufacturing method of a silicon single crystal using such a quartz glass crucible.

### BACKGROUND ART

Most silicon single crystals that become a substrate material of a semiconductor device are manufactured by a CZ method. In the CZ method, a polycrystalline silicon raw material is melted in a quartz glass crucible to generate a silicon melt, a seed crystal is immersed in the silicon melt, and the seed crystal is gradually pulled up while rotating the quartz glass crucible and the seed crystal. Thus, a large single crystal is grown at the lower end of the seed crystal. According to the CZ method, it is possible to increase the yield of large-diameter silicon single crystals.

A quartz glass crucible (silica glass crucible) is a container made of silica glass that holds a silicon melt during a silicon single crystal pulling up step. Therefore, the quartz glass crucible is required to have high durability to withstand a long duration use without being deformed at high temperature not less than the melting point of silicon. In addition, the quartz glass crucible is required to have high purity for preventing impurity contamination of the silicon single crystal.

It is known that a brown ring-shaped crystal of cristobalite, which is called brown ring, grows on the inner surface of the quartz glass crucible that comes into contact with the silicon melt when the silicon single crystal is pulled up. When the brown ring is peeled from the surface of the crucible and mixed into the silicon melt, it may be transported to the solid-liquid interface by melt convection and incorporated into the single crystal. Peeling of cristobalite causes dislocation in the silicon single crystal. Therefore, the inner surface of the crucible is actively crystallized by a crystallization accelerator to prevent the peeling of the crystal grains.

Regarding a method of reinforcing an inner surface of a crucible by crystallization, for example, Patent Literature 1 describes a method of manufacturing a highly durable crucible by using calcium, strontium, and barium as a crystallization accelerator. Patent Literature 2 describes a devitrification agent for a crucible with improved efficiency than a conventional one. The devitrification agent, which includes barium, and tantalum, tungsten, germanium, tin, or a combination of two or more thereof, is melted into a crucible during construction, applied to the surface of a finished crucible, and/or added to the silicon melt used for crystal pulling up.

Patent Literature 3 describes a surface-treated crucible with improved dislocation-free performance. The crucible includes first and second devitrification accelerators distributed on the inner and outer surfaces, respectively, of the sidewall formation of the main body of vitreous silica. The first devitrification accelerator is distributed such that a first layer of substantially devitrified silica is formed on the inner surface of the crucible, which comes into contact with the molten semiconductor material when the semiconductor material melts in the crucible during crystal growth. In addition, the second devitrification accelerator is distributed such that a second layer of substantially devitrified silica is formed on the outer surface of the crucible when the semiconductor material melts in the crucible during crystal growth.

Patent Literature 4 describes a quartz glass crucible that can withstand a very long duration single crystal pulling up step such as multi-pulling up. This quartz glass crucible includes a crucible base body consisting of quartz glass, and first and second crystallization accelerator-containing coating films formed on the inner and outer surfaces of the crucible base body, respectively. The first and second crystallization accelerator-containing coating films contain a polymer, and the crystallization accelerator is a water-insoluble barium compound. By the action of the crystallization accelerator, a crystal layer composed of an aggregate of dome-shaped or columnar crystal grains is formed on the surface layer portions of the inner and outer surfaces of the crucible base body.

Patent Literature 5 describes a method of measuring a concentration profile of impurities in a depth direction from a surface of a crucible by repeating a step of bringing an etchant into contact with a specific region of a surface of a sample of the quartz crucible to dissolve the surface and recovering the etchant at a plurality of times, and measuring a concentration of impurities contained in the recovered etchant, and a measuring jig used for the method.

### BACKGROUND ART LITERATURE

### Patent Literature

Patent Literature 1: Japanese Patent Laid-open Publication No. 2012-211082

Patent Literature 2: Japanese Unexamined Patent Application No. 2019-509969

Patent Literature 3: Japanese Patent Laid-open Publication No. H09-110590

Patent Literature 4: Japanese Patent Laid-open Publication No. 2020-200236

Patent Literature 5: Japanese Patent Laid-open Publication No. 2019-066262

### SUMMARY OF INVENTION

### Problems to be Solved by the Invention

As described above, the method of applying a crystallization accelerator is effective in uniformly crystallizing the inner surface of the crucible. Examples of a method of applying the crystallization accelerator include application with a brush, application with a spray, and the like. In the coating method using a brush, unevenness of concentration in the in-plane direction tends to occur, and a portion that does not crystallize is likely to be generated in the coating region. In the coating method using a spray, the crystallization accelerator sprayed in a misty manner is scattered, and a portion that does not crystallize is likely to be generated near the boundary between the coating region and the uncoated region. Although the inner surface of the crucible is melted away by contact with the silicon melt, since the melting rate of the glass portion that does not crystallize is faster than that of the crystallized portion, in a case where the pulling up progresses, the crystallized portion remains and is likely to be separated from the glass surface. In a case where the crystal grains separated from the inner surface of the crucible enter the silicon melt, the dislocation in the silicon single crystal is caused, which adversely affects the single crystal yield.

To prevent a portion that does not crystallize from remaining, a method of increasing the concentration of the crystallization accelerator to promote crystallization is effective. However, in a case of making the crystallization accelerator into high concentration, the crystallization rate in not only the in-plane direction but also the depth direction is increased, and the crystal layer is excessively thickened. There is a problem in that in a case where such a thick crystal layer is formed on the inner surface of the crucible, the crystal layer is more likely to be peeled.

The present invention has been made in view of the above-described problems, and an object of the present invention is to provide a quartz glass crucible capable of forming a uniform and thin crystal layer on an inner surface by heating during a crystal pulling up step, and a manufacturing method thereof. Another object of the present invention is to provide a manufacturing method of a silicon single crystal using such a quartz glass crucible.

### Means for Solving the Problems

The present inventors have conducted intensive studies on a mechanism of crystallization of an inner surface of a crucible in a case where a crystallization accelerator is applied, and as a result, have found that, by making a concentration of impurities in a depth direction in a vicinity of the inner surface of the crucible into a specific range, crystallization of the inner surface by heating during crystal pulling up may be faster in an in-plane direction than in the depth direction, and thus the present invention has been completed.

The present invention is based on such technical findings, and a quartz glass crucible for pulling up a silicon single crystal according to the embodiment of the present invention includes a crucible base body consisting of silica glass, and a crystallization accelerator-containing coating film formed on an inner surface of the crucible base body, in which a concentration of Fe contained in a first depth region of at least 0.5 mm or less from the inner surface is higher than a concentration of Al contained in the first depth region. In this way, in the quartz glass crucible according to the embodiment of the present invention, a concentration of iron contained in the depth region from the inner surface of the crucible to at least 0.5 mm is higher than a concentration of aluminum contained in the depth region, and thus a crystallization rate of the inner surface in an in-plane direction can be increased. Thereby, even in a case where coating unevenness of the crystallization accelerator occurs on the inner surface, the inner surface of the crucible is finally covered with a uniform crystal plane, and thus the peeling of the crystallized portion can be suppressed, and the dislocation of the silicon single crystal pulled up from the silicon melt in the crucible can be prevented.

In the present invention, it is preferable that a concentration of Ca contained in the first depth region is higher than the concentration of Al contained in the first depth region. Since calcium also acts in the same manner as iron and crystallization of the inner surface of the crucible is likely to spread in the in-plane direction, a uniform crystal plane can be formed on the inner surface of the crucible and peeling of the crystallized portion can be suppressed.

In the present invention, it is preferable that a concentration of a metal element contained in a second depth region of 2 mm or less from the inner surface is lower than a concentration of the metal element contained in a third depth region of 2 mm or more and 5 mm or less from the inner surface, and the metal element is B, Mg, or Cr. In a case where boron, magnesium, or chromium exists in the glass, a microstructure around the atom is a regularly arranged crystal structure. In a case where the impurities are present from the inner surface to a certain depth, the crystallization rate in the depth direction from the inner surface toward the outer surface side is increased, and thus it is desirable that the impurities are reduced. Moreover, it is possible to prevent the contamination of the silicon melt by melting away the inner surface of the crucible.

In the present invention, the concentration of the crystallization accelerator in the crystallization accelerator-containing coating film is preferably 1.0×10¹² to 2.6×10¹⁵ atoms/cm². In a case where the concentration of the crystallization accelerator is higher than 2.6×10¹⁵ atoms/cm², the crystallized particles are not random and crystallize in a form oriented in the depth direction. Therefore, the crystallization rate in the depth direction is increased, the crystallization accelerator is consumed (diffused) in the depth direction, and the crystallization is unlikely to spread in the in-plane direction. However, in a case where the concentration of the crystallization accelerator is 2.6×10¹⁵ atoms/cm² or less, crystallization in the depth direction can be suppressed and crystallization in the in-plane direction can be promoted.

In a case where the quartz glass crucible according to the embodiment of the present invention is subjected to a heat treatment at 1,580° C., a ratio of a crystallization rate in the in-plane direction to a crystallization rate in the depth direction is preferably 1.5 to 400. In a case where the ratio of the crystallization rate in the in-plane direction to the crystallization rate in the depth direction is less than 1.5, the crystal layer is excessively thick, and thus the crystal grains are likely to be peeled. In addition, in a case where the ratio of the crystallization rate in the in-plane direction to the crystallization rate in the depth direction is more than 400, there is a concern that a sufficient thickness of the crystal layer cannot be obtained and a portion where the crystal layer disappears due to a reaction with the silicon melt during the pulling up may be generated. In a case where the ratio of the crystallization rate in the in-plane direction to the crystallization rate in the depth direction is 1.5 to 400, the occurrence of such issues can be prevented.

In the present invention, it is preferable that, in the heat treatment, a temperature rising time from room temperature to 1,580° C. is 2.5 hours, a holding time at 1,580° C. is 10 hours, and an atmospheric pressure during the heat treatment is 20 Torr. In a case where the crystallization rate in the in-plane direction of the inner surface is higher than the crystallization rate in the depth direction in a case where the heat treatment is performed under such conditions, the crystallization in the in-plane direction proceeds in the same manner even during the actual crystal pulling up. Therefore, a thin and uniform crystal layer can be formed on the inner surface of the crucible base body without unevenness.

In the present invention, a length in an in-plane direction of the crystallization that spreads on the inner surface after the heat treatment is preferably 1 to 60 mm. In a case where the length of crystallization is shorter than 1 mm, a region that does not crystallize may be generated due to unevenness of the crystallization accelerator applied to the inner surface. In a case where the length of crystallization is longer than 60 mm, crystallization occurs up to the upper end of the crucible opening portion, and the risk of causing dislocation due to the falling of the crystal layer peeled by excessive crystallization into the silicon melt increases.

In the present invention, it is preferable that the crystallization accelerator contained in the crystallization accelerator-containing coating film is Ba, and a concentration of Ba in the crystal layer formed after the heat treatment is less than 1 ppm.

In the present invention, it is preferable that the crucible base body has a cylindrical sidewall, a bottom, and a corner provided between the sidewall and the bottom, a rim vicinity region from an upper end of a rim to at least 20 mm downward from the rim on the inner surface of the crucible base body, is a crystallization accelerator uncoated region, and the crystallization accelerator-containing coating film is formed on the entire inner surface excluding the uncoated region.

In addition, a manufacturing method of a quartz glass crucible according to the embodiment of the present invention includes a step of manufacturing a crucible base body consisting of silica glass, and a step of forming a crystallization accelerator-containing coating film on an inner surface of the crucible base body, in which the step of manufacturing the crucible base body includes a step of forming a deposited layer of raw material particles by sequentially charging natural quartz particles and synthetic quartz particles into an inner surface of a rotating mold, and an arc step of arc-melting the deposited layer of the raw material particles from an inside of the mold, and the arc step includes a first heating step, a second heating step which is arc heating with a lower output and a longer duration than the first heating step, and a third heating step which is arc heating with a lower output than the second heating step and a longer duration than the first heating step. In this case, it is preferable that the output of the first heating step is 110% of the output of the second heating step, and it is preferable that the output of the third heating step is 55% of the output of the second heating step. According to the present invention, it is possible to manufacture a quartz glass crucible in which a crystallization rate in an in-plane direction of an inner surface of a crucible base body is faster than a crystallization rate in a depth direction.

In the present invention, it is preferable that the arc step includes a transparent layer forming step of arc-melting a deposited layer of raw material particles while performing vacuuming from an inside of a mold, and a bubble layer forming step of arc-melting while stopping the vacuuming or reducing a suction force, and the first heating step is started at a time of starting the transparent layer forming step and is finished in the middle of the transparent layer forming step. In this manner, the concentration of aluminum present in the depth region from the inner surface of the crucible base body to 0.5 mm can be reduced.

Furthermore, in the manufacturing method of a silicon single crystal according to the present invention, a silicon single crystal is pulled up using the quartz glass crucible according to the present invention having the above-described features. According to the present invention, the manufacturing yield of a silicon single crystal can be increased.

### Effects of the Invention

According to the present invention, it is possible to provide a quartz glass crucible capable of forming a uniform and thin crystal layer on an inner surface by heating during a crystal pulling up step, and a manufacturing method thereof. In addition, according to the present invention, it is possible to provide a manufacturing method of a silicon single crystal, in which a long duration crystal growing step can be performed by using such a quartz glass crucible.

### BRIEF DESCRIPTION OF THE DRAWINGS

FIG. 1 is a schematic perspective view illustrating a configuration of a quartz glass crucible according to an embodiment of the present invention.

FIG. 2 is a schematic side sectional view of the quartz glass crucible illustrated in FIG. 1.

FIG. 3 is a schematic view for describing a metal impurity profile in a depth direction from an inner surface of a crucible base body.

FIG. 4 is a schematic diagram illustrating a manufacturing method of a quartz glass crucible according to a rotational molding method.

FIG. 5 is a diagram for explaining a manufacturing method of silicon single crystal (single crystal pulling up step) using the quartz glass crucible according to the present embodiment, and is a schematic sectional view illustrating a configuration of a single crystal pulling apparatus.

### MODE FOR CARRYING OUT THE INVENTION

Hereinafter, preferred embodiments of the present invention are described in detail with reference to the accompanying drawings.

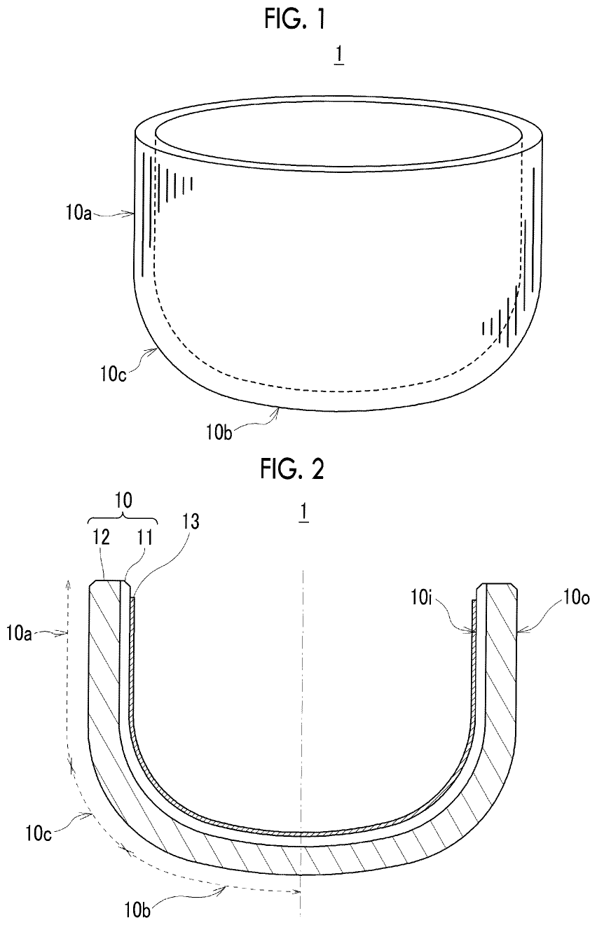

FIG. 1 is a schematic perspective view illustrating the configuration of a quartz glass crucible according to an embodiment of the present invention. In addition, FIG. 2 is a schematic side sectional view of the quartz glass crucible illustrated in FIG. 1.

As shown in FIG. 1 and FIG. 2, a quartz glass crucible 1 is a silica glass container for holding a silicon melt and has a cylindrical sidewall 10a, a bottom 10b provided below the sidewall 10a, and a corner 10c provided between the sidewall 10a and the bottom 10b. The bottom 10b is preferably a so-called round bottom that is gently curved, but may also be a so-called flat bottom. The corner 10c is a portion having a larger curvature than the bottom 10b. The boundary position between the sidewall 10a and the corner 10c and the boundary position between the bottom 10b and the corner 10c are positions where the curvature begins to change from a small curvature to a large curvature.

The aperture (diameter) of the quartz glass crucible 1 also varies depending on the diameter of the silicon single crystal ingot that is pulled up from the silicon melt, but is 18 inches (approximately 450 mm) or more, preferably 22 inches (approximately 560 mm) or more, and particularly preferably 32 inches (approximately 800 mm) or more. This is because such a large crucible is used for pulling up a large silicon single crystal ingot having a diameter of 300 mm or more, and is required not to affect the quality of the single crystal even with the long duration use.

The wall thickness of the crucible varies slightly depending on its part, but it is preferable that the wall thickness of the sidewall 10a of the crucible of 18 inches or more is 6 mm or more, and the wall thickness of the sidewall 10a of the crucible of 22 inches or more is 7 mm or more, and the wall thickness of the sidewall 10a of the crucible of 32 inches or more is 10 mm or more. As a result, a large amount of silicon melt can be stably held at high temperature. It is preferable that the wall thickness of the corner 10c of the crucible is the largest and the wall thickness of the sidewall 10a and the bottom 10b of the crucible is smaller than that of the corner 10c of the crucible.

As shown in FIG. 2, a quartz glass crucible 1 includes a crucible base body 10 consisting of silica glass and a crystallization accelerator-containing coating film 13 formed on the inner surface 10i of the crucible base body 10. The crucible base body mainly has a two-layer structure, and has a transparent layer 11 containing no bubbles (non-bubble layer) and a bubble layer 12 containing a large number of minute bubbles (opaque layer), and the crystallization accelerator-containing coating film 13 is provided inside the transparent layer 11.

The transparent layer 11 is a glass layer that configures the inner surface 10i of the crucible base body 10, which comes into contact with the silicon melt, and is provided to prevent a yield of the silicon single crystals from decreasing due to bubbles in the silica glass. Since the inner surface 10i of the crucible reacts with the silicon melt to melt away, the bubbles in the vicinity of the inner surface of the crucible cannot be trapped in the silica glass and the bubbles burst due to thermal expansion, and thus the crucible fragments (silica fragments) may be peeled. In a case where the crucible fragments released into the silicon melt are transported by melt convection to a growth interface of the silicon single crystal and are incorporated into the silicon single crystal, they cause dislocation in the silicon single crystal. In addition, in a case where the bubbles released into the silicon melt float up and reach a solid-liquid interface and are incorporated into the single crystal, they cause pinhole formation in the silicon single crystal.

Containing no bubbles in the transparent layer 11 means having a bubble content and a bubble size to the extent that the single crystallization rate does not decrease due to bubbles. Such a bubble content is, for example, 0.1 vol % or less, and the bubble diameter is, for example, 100 μm or less.

The thickness of the transparent layer 11 is preferably 0.5 to 10 mm, and is set to an appropriate thickness for each portion of the crucible such that the bubble layer 12 is not exposed by completely vanishing the transparent layer 11 due to melting away during a crystal pulling up step. The transparent layer 11 is preferably provided over the entire crucible from the sidewall 10a to the bottom 10b of the crucible, but the transparent layer 11 can be omitted at the upper end portion of the crucible that does not come into contact with the silicon melt.

The air bubble content and the diameter of the air bubbles in the transparent layer 11 can be measured nondestructively using an optical detecting means. The optical detecting means includes a light-receiving device which receives transmitted light or reflected light of the light irradiating the crucible. As the light-receiving device, a digital camera including an optical lens and an imaging element can be used. As the irradiation light, X-rays, laser light, and the like as well as visible light, ultraviolet light, and infrared light can be used. Measurement results obtained by the optical detecting means are received by an image processing device to calculate the diameter of bubbles and the bubble content per unit volume.

The bubble layer 12 is a principal glass layer of the crucible base body 10 located on the outer side than the transparent layer 11 and is provided to improve the heat retention property of the silicon melt in the crucible, and to heat the silicon melt in the crucible as uniformly as possible by dispersing radiant heat from a heater in a single crystal pulling apparatus. Therefore, the bubble layer 12 is provided over the entire crucible from the sidewall 10a to the bottom 10b. The thickness of the bubble layer 12 is substantially equal to a value obtained by subtracting the thickness of the transparent layer 11 from the thickness of the crucible base body 10, and varies depending on the part of the crucible.

The bubble content of the bubble layer 12 is higher than the transparent layer 11 and is preferably more than 0.1 vol % and 5 vol % or less. This is because in a case where the bubble content of the bubble layer 12 is 0.1 vol % or less, the bubble layer 12 cannot exhibit the required heat retention function. In addition, this is because when the bubble content of the bubble layer 12 exceeds 5 vol %, the crucible may be deformed due to the thermal expansion of the bubbles and decrease the yield of the single crystals, and further heat transfer property is insufficient. From the viewpoint of the balance between the heat retention property and the heat transfer property, the bubble content of the bubble layer 12 is particularly preferably 1 to 4 vol %. It should be noted that the above-mentioned bubble content is a value obtained by measuring the crucible before use under a room temperature environment. The bubble content of the bubble layer 12 can be obtained, for example, by measuring the specific gravity (Archimedes method) of an opaque silica glass piece cut out from the crucible.

In order to prevent contamination of the silicon melt, the silica glass configuring the inside (innermost surface layer) of the transparent layer 11 is preferably of high purity. Therefore, the crucible base body 10 preferably has a two-layer structure of a synthetic silica glass layer (synthetic layer) formed from synthetic quartz particles and a natural silica glass layer (natural layer) formed from natural quartz particles. Synthetic quartz particles can be manufactured by vapor-phase oxidation of silicon tetrachloride (SiCl₄) (dry synthesis method) or by hydrolysis of silicon alkoxide (sol-gel method). In addition, natural quartz particles are manufactured by pulverizing natural minerals containing α-quartz as a main component into granules.

The two-layer structure of a synthetic silica glass layer and a natural silica glass layer can be manufactured by depositing natural quartz particles along the inner surface of the mold for manufacturing the crucible, depositing synthetic quartz particles thereon, and melting these raw material quartz particles with Joule heat generated by arc discharge. The arc melting step includes strongly evacuating from outside of the deposited layer of raw material quartz particles to remove bubbles and form the transparent layer 11, stopping or weakening the evacuation to form the bubble layer 12. Therefore, the interface between the synthetic silica glass layer and the natural silica glass layer does not necessarily coincide with the interface between the transparent layer 11 and the bubble layer 12, but the synthetic silica glass layer preferably has, as similar to the transparent layer 11, a thickness to the extent that does not completely vanish due to melting away of the inner surface of the crucible during the single crystal pulling up step.

The quartz glass crucible 1 according to the present embodiment has a configuration in which the inner surface 10i of the crucible base body 10 is covered with a crystallization accelerator-containing coating film 13. The crystallization accelerator plays a role in accelerating crystallization of the inner surface 10i of the crucible base body 10 during the single crystal pulling up step. The crystallization accelerator is preferably barium (Ba) or strontium (Sr), which are Group 2a elements, and particularly preferably barium. This is because barium has a smaller segregation coefficient than silicon, is stable at room temperature, and is easy to handle. In addition, barium has an advantage that the crystallization rate of the crucible is not attenuated with crystallization and orientation growth is induced more strongly than other elements.

The crystallization accelerator-containing coating film 13 is preferably formed on the entire inner surface 10i of the crucible base body 10 excluding a rim vicinity region from the upper end of the rim to at least 20 mm downward from the rim. The reason for excluding the rim vicinity region is that the vicinity of the upper end of the rim does not come into contact with the silicon melt and does not necessarily need to be crystallized. This is also because peeling of crystals is occurred in the vicinity of the upper end of the rim during crystallization and thus the crystal grains mixed in the silicon melt cause dislocations in the silicon single crystal.

The concentration of the crystallization accelerator contained in the crystallization accelerator-containing coating film 13 is preferably 1.0×10¹² to 2.6×10¹⁵ atoms/cm². In a case where the concentration of the crystallization accelerator is higher than 2.6×10¹⁵ atoms/cm², orientation of the crystallized particles are not random and crystallize in a form oriented in the depth direction. Therefore, the crystallization rate in the depth direction is increased, the crystallization accelerator is consumed (diffused) in the depth direction, and the crystallization is unlikely to spread in the in-plane direction. However, in a case where the concentration of the crystallization accelerator is relatively low, the crystallization in the depth direction of the inner surface 10i of the crucible base body 10 can be suppressed, and the crystallization in the in-plane direction can be accelerated. Therefore, it is possible to achieve uniform crystallization of the inner surface 10i of the crucible base body 10.

The thickness of the crystallization accelerator-containing coating film 13 is not particularly limited, but is preferably 0.1 to 50 μm and particularly preferably 1 to 20 μm. This is because in a case where the thickness of the crystallization accelerator-containing coating film 13 is too thin, the peel strength of the crystallization accelerator-containing coating film 13 is weak, and the peeling of the crystallization accelerator-containing coating film 13 causes nonuniform crystallization. Also in a case where the crystallization accelerator-containing coating film 13 is too thick, the peel strength is lowered and the crystallization is nonuniform.

To crystallize the inner surface of the crucible as uniformly and thinly as possible by heating in the crystal pulling up step, it is necessary that the crystallization rate of the crystal layer in the in-plane direction is higher than the crystallization rate in the depth direction. In particular, the ratio of the crystallization rate in the in-plane direction to the crystallization rate in the depth direction is preferably 1.5 to 400. In a case where the ratio of the crystallization rate in the in-plane direction to the crystallization rate in the depth direction is less than 1.5, the crystal layer is excessively thick, and thus the crystal grains are likely to be peeled. In addition, in a case where the ratio of the crystallization rate in the in-plane direction to the crystallization rate in the depth direction is more than 400, there is a concern that a sufficient thickness of the crystal layer cannot be obtained and a portion where the crystal layer disappears due to a reaction with the silicon melt during the pulling up may be generated.

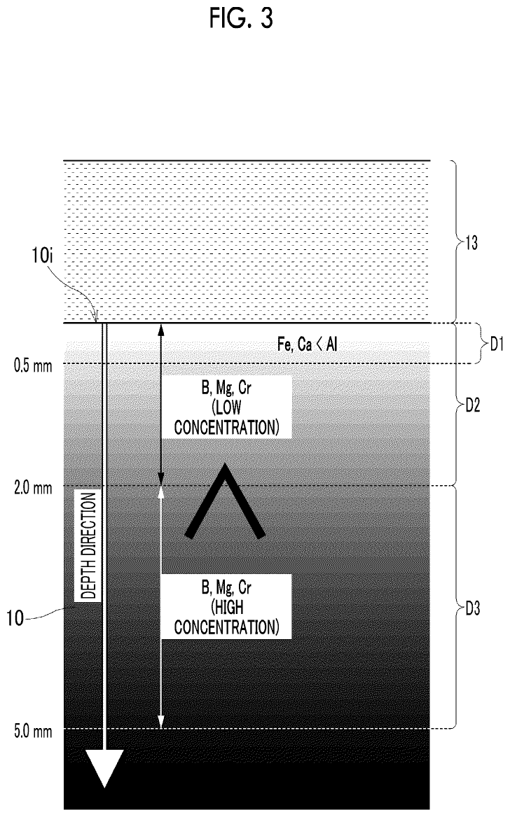

FIG. 3 is a schematic view for describing a metal impurity profile in a depth direction from an inner surface 10i of a crucible base body 10.

As shown in FIG. 3, to make the crystallization rate of the inner surface 10i of the crucible base body 10 in the in-plane direction higher than that in the depth direction, the concentration of aluminum (Al) contained in the topmost surface layer portion of the crucible base body 10 is preferably lower than the concentrations of iron (Fe) and calcium (Ca) contained in the topmost surface layer portion. Specifically, the concentration of Al contained in the depth region D1 (first depth region) from the inner surface 10i of the crucible base body 10 to at least 0.5 mm is preferably lower than the concentration of Fe contained in the depth region D1. In addition, the concentration of Al contained in the depth region D1 from the inner surface 10i of the crucible base body 10 to at least 0.5 mm is preferably lower than the concentration of Ca contained in the depth region D1.

Al exists as an anion (Al⁻) in silica glass (quartz glass) and attracts a cation. Therefore, in a case where Al exists in the glass, the diffusion of the crystallization accelerator is suppressed, and the crystallization rate is slowed down. However, Fe and Ca do not trap the crystallization accelerator, and accelerate crystallization. Therefore, in a case where Fe and Ca exist at a higher concentration than Al, crystallization is likely to spread in the in-plane direction. In addition, by reducing the Al concentration on the inner surface 10i of the crucible base body 10, a decrease in viscosity of glass on the deeper side than the crystal layer can be prevented and the risk of peeling of the crystal layer due to deformation can be reduced.

Fe and Ca of the inner surface 10i of the crucible base body 10 cause impurity contamination of the silicon single crystal, but in a case of a very small amount, they serve as a starting point of crystallization of the inner surface 10i and have an effect of easily spreading the crystallization in an in-plane direction. In the present invention, the content of Al in the inner surface 10i of the crucible base body 10 is further smaller than those of Fe and Ca. In a case where Al exists in a large amount on the inner surface 10i, the actions of Fe and Ca are weakened by the action of Al, and the crystallization of the inner surface 10i is less likely to proceed in the in-plane direction. However, since the concentration of Al is lower than the concentrations of Fe and Ca, the crystallization of the inner surface 10i in the in-plane direction can be accelerated.

Although details will be described later, such a concentration balance of Al, Fe, and Ca can be realized by using synthetic quartz particles having a low Al concentration as a raw material for the inner surface 10i of the crucible base body 10 and performing arc discharge with a low output for a long duration at the end of arc melting of the raw material particles. In a case where the arc time at a low output is too short, no change is observed in the concentrations of Fe and Ca on the inner surface 10i, and in a case where the arc time at a low output is too long, the concentration of impurities on the inner surface 10i is too high. Therefore, it is necessary to appropriately adjust the arc time. As described above, by performing the arc with a low output, the concentrations of Fe and Ca can be made higher than that of Al. Furthermore, it is preferable to increase the arc output in the forming step of the transparent layer 11 at the beginning of arc melting. Accordingly, the concentration of aluminum existing in the depth region from the inner surface 10i of the crucible base body 10 to 0.5 mm can be reduced.

In the present embodiment, it is preferable that a concentration of boron (B) contained in a depth region D2 (second depth region) of 2 mm or less from the inner surface 10i of the crucible base body 10 is lower than a concentration of B contained in a depth region D3 (third depth region) of 2 mm or more and 5 mm or less from the inner surface 10i. The same applies to magnesium (Mg) and chromium (Cr) as in B. In a case where B, Mg, and Cr exist in the glass, a microstructure around the atoms is a regularly arranged crystal structure. Therefore, in a case where a large amount of the above-described impurities exists in the depth region D2 having a depth of 2 mm or less from the inner surface 10i of the crucible base body 10, crystallization in the depth direction from the inner surface 10i is accelerated, and it is difficult to accelerate crystallization of the inner surface 10i in the in-plane direction. However, in a case where a small amount of the impurities exists within the depth region D2 of 2 mm or less from the inner surface 10i, crystallization in the depth direction can be suppressed from the inner surface 10i, and crystallization in the in-plane direction can be accelerated. In addition, it is possible to prevent the impurities contamination of the silicon melt due to the melting away of the inner surface 10i of the crucible base body 10.

In the quartz glass crucible according to the present embodiment, since the crystallization rate in the in-plane direction of the inner surface of the crucible is higher than the crystallization rate in the depth direction in a case where the heat treatment is performed at 1,500° C. to 1,600° C., the crystallization in the in-plane direction of the inner surface of the crucible can be accelerated in the crystal pulling up step. As the heat treatment conditions, the temperature is raised from room temperature to 1,580° C. over 2.5 hours, and then hold at 1,580° C. for 10 hours. In a case where the atmospheric pressure is 20 Torr, a ratio of a crystallization rate in an in-plane direction to a crystallization rate in a depth direction of the inner surface of the crucible after the heat treatment is preferably 1.5 to 400.

A length in an in-plane direction of the crystallization that spreads on the inner surface after the heat treatment is preferably 1 to 60 mm. In a case where the length of crystallization in the in-plane direction is shorter than 1 mm, a portion that are not crystallized is likely to be generated in a case where there is unevenness in the crystallization accelerator applied to the inner surface, and in a case where the length of crystallization in the in-plane direction is longer than 60 mm, crystallization occurs up to the upper end of the crucible opening portion, and the risk of causing dislocation due to the falling of the crystal layer peeled by excessive crystallization into the silicon melt increases.

It should be noted that the length of crystallization (crystal growth) can be obtained as the longest distance from the starting point of crystallization to the outermost periphery of the crystallization region. Alternatively, the length of crystallization can be obtained as the difference ΔB between the boundary position B1 between the coating region of the crystallization accelerator and the uncoated region and the boundary position B2 between the crystallized region after the heat treatment and the non-crystallized region, ΔB=B2−B1.

The concentration of barium in the crystal layer formed on the inner surface 10i of the crucible base body 10 after the heat treatment is preferably less than 1 ppm. By crystallizing the inner surface 10i of the crucible base body 10 without using a large amount of the crystallization accelerator, the crystallization of the crucible in the in-plane direction can be accelerated, and a thin crystal layer can be formed on the inner surface 10i of the rutile base 10 without unevenness.

The quartz glass crucible 1 according to the present embodiment can be manufactured by applying a crystallization accelerator to the inner surface 10i of the crucible base body 10 after manufacturing the crucible base body 10 by a so-called rotational molding method.

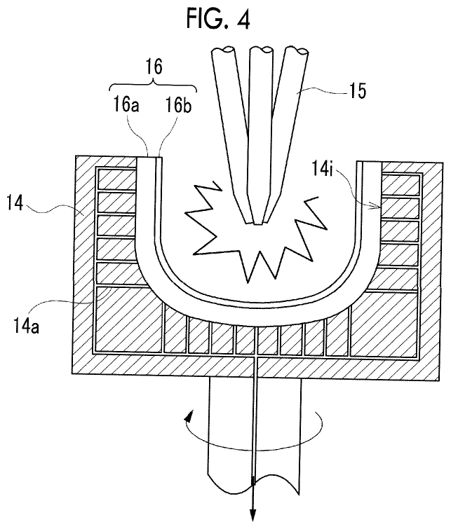

FIG. 4 is a schematic diagram illustrating a manufacturing method of the quartz glass crucible according to a rotational molding method.

As shown in FIG. 4, In the rotational molding method, a carbon mold 14 having a cavity matching the outer shape of the crucible is prepared, and the natural quartz particles 16a and the synthetic quartz particles 16b are sequentially filled along the inner surface 14i of the rotating carbon mold 14 to form a deposited layer 16 of raw material quartz particles. The raw material quartz particles stay in a fixed position while sticking to the inner surface 14i of the carbon mold 14 by centrifugal force, and are maintained in a crucible shape.

Next, the arc electrode 15 is installed in the carbon mold 14, and a deposited layer 16 of the raw material quartz particles is arc-melted from the inside of the carbon mold 14. Specific conditions such as heating time and heating temperature are appropriately determined in consideration of the properties of the raw material quartz particles, the size of the crucible, and the like.

During the arc melting, the amount of bubbles in the molten quartz glass is controlled by vacuuming the deposited layer 16 of the raw material quartz particles from the large number of vent holes 14a provided in the inner surface 14i of the carbon mold 14. Specifically, at the start of arc melting, the deposited layer 16 of the raw material quartz particles is vacuumed to form the transparent layer 11, and after the formation of the transparent layer 11, the vacuuming of the raw material quartz particles is stopped or the suction force is reduced to form the bubble layer 12.

Since the arc heat is transferred from the inside to the outside of the deposited layer 16 of the raw material quartz particles to melt the raw material quartz particles, by changing decompression conditions at the timing at which the raw material quartz particles start to melt, the transparent layer 11 and the bubble layer 12 can be made separately. That is, in a case where decompression melting for strengthening the decompression is performed at the timing at which raw material quartz particles melt, atmosphere gas is not trapped in the glass, and thus the molten quartz becomes silica glass containing no bubbles. In addition, in a case where normal melting (atmospheric pressure melting) for weakening the decompression is performed at the timing at which raw material quartz particles melt, atmosphere gas is trapped in the glass, and thus the molten quartz becomes silica glass containing a large number of bubbles.

To make the concentrations of Fe and Ca on the inner surface 10i side of the crucible base body 10 higher than that of Al, arc melting is performed for a long duration at a low output at the end of the arc melting step. The concentrations of Fe and Ca on the inner surface 10i of the crucible base body 10 tend to increase as the arc melting time at a low output increases. Since the concentration of Fe and Ca on the inner surface 10i does not change in a case where the arc melting time at a low output is too short, and the concentration of impurities on the inner surface 10i is excessively high in a case where the arc melting time is too long, the arc melting time needs to be set to an appropriate time.

Subsequently, the arc melting is terminated and the crucible is cooled. As described above, the crucible base body 10 is completed, in which the transparent layer 11 and the bubble layer 12 are provided in that order from the inside toward the outside of the crucible wall. As described above, the crucible base body 10 according to the present embodiment can be manufactured by filling the carbon mold 14 which is being rotated with the natural quartz particles 16a as an outer layer raw material, filling the carbon mold 14 with the synthetic quartz particles 16b as an inner layer raw material, and arc-melting the deposited layer 16 of the raw material quartz particles.

Next, the shape of the crucible base body 10 is adjusted by cutting the rim portion, or the like, then cleaned with a cleaning liquid, and further rinsed with pure water. The cleaning liquid is preferably prepared by diluting hydrofluoric acid of semiconductor grade or higher with pure water of TOC≤2 ppb to adjust to 10 to 40 w %.

Next, the crystallization accelerator is applied to the inner surface 10i of the crucible base body 10. It is preferable that a brush is used for the application of the coating liquid. To uniformly disperse the crystallization accelerator on the inner surface 10i, a coating liquid is preferably used, in which the crystallization accelerator is dissolved in pure water (15° C. to 25° C., 17.2 MΩ or more, and TOC≤2 ppb). To increase the solubility of the crystallization accelerator, it is preferable to stir the coating liquid using a stirrer.

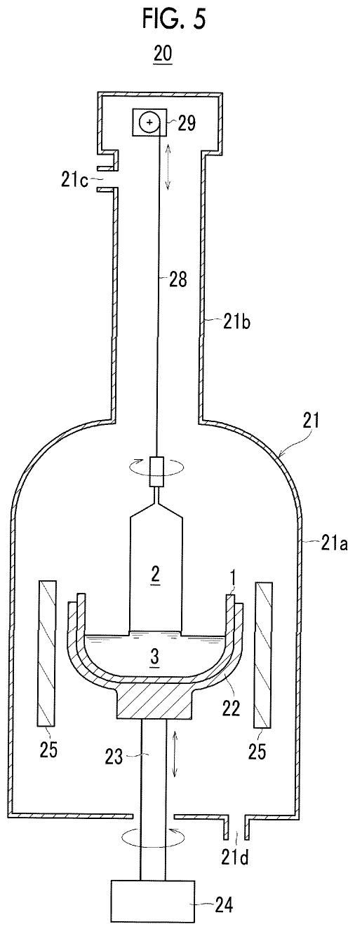

FIG. 5 is a diagram for explaining a manufacturing method of silicon single crystal (single crystal pulling up step) using the quartz glass crucible according to the present embodiment, and is a schematic sectional view illustrating a configuration of a single crystal pulling apparatus.

As shown in FIG. 5, a single crystal pulling apparatus 20 is used for the pulling up step of a silicon single crystal by the CZ method. The single crystal pulling apparatus 20 includes a water-cooled chamber 21, a quartz glass crucible 1 holding a silicon melt in the chamber 21, a carbon susceptor 22 holding the quartz glass crucible 1, a rotating shaft 23 supporting the carbon susceptor 22 to be capable of rotation and elevation, a shaft driving mechanism 24 that rotates and elevation-drives the rotating shaft 23, a heater 25 that is arranged around the carbon susceptor 22, a single crystal pulling-up wire 28 that is arranged above the quartz glass crucible 1 and on the same axis with the rotating shaft 23, and a wire winding mechanism 29 arranged above the chamber 21.

The chamber 21 is configured by a main chamber 21a and a slender cylindrical pull chamber 21b which is connected to an upper opening of the main chamber 21a. The quartz glass crucible 1, the carbon susceptor 22, and the heater 25 are provided in the main chamber 21a. A gas entry 21c for introducing inert gas (purge gas) such as argon gas or a dopant gas into the main chamber 21a is provided in the upper portion of the pull chamber 21b, and a gas outlet 21d for discharging atmospheric gas inside the main chamber 21a is provided in the lower portion of the main chamber 21a.

The carbon susceptor 22 is used to hold the shape of the quartz glass crucible 1 which is softened at high temperature, and holds the quartz glass crucible 1 to wrap around it. The quartz glass crucible 1 and the carbon susceptor 22 configure a double-structured crucible that supports the silicon melt in the chamber 21.

The carbon susceptor 22 is fixed to the upper end of the rotating shaft 23, and the lower end of the rotating shaft 23 passes through the bottom of the chamber 21 and is connected to a shaft driving mechanism 24 provided outside of the chamber 21.

The heater 25 is used to melt the polycrystalline silicon raw material filled in the quartz glass crucible 1 to generate the silicon melt 3, as well as to keep a molten state of the silicon melt 3. The heater 25 is a resistance heating type carbon heater, and is provided surrounding the quartz glass crucible 1 in the carbon susceptor 22.

Although the amount of the silicon melt 3 in the quartz glass crucible 1 decreases as a silicon single crystal 2 grows, the quartz glass crucible 1 is raised such that the height of the melt surface is constant.

The wire winding mechanism 29 is arranged above the pull chamber 21b, the wire 28 extends downward from the wire winding mechanism 29 passing through the interior of the pull chamber 21b, and a distal end of the wire 28 reaches the inner space of the main chamber 21a. This figure shows a state in which the silicon single crystal 2 in the middle of growth is suspended on the wire 28. When the silicon single crystal 2 is pulled up, the wire 28 is gradually pulled up while rotating the quartz glass crucible 1 and the silicon single crystal 2 individually to grow the silicon single crystal 2.

During the single crystal pulling up step, the inner surface of the crucible crystallizes, and the crystallization of the inner surface of the crucible advances uniformly by the action of the crystallization accelerator, and thus dislocations in the silicon single crystal due to peeling of brown rings can be prevented. In addition, the quartz glass crucible 1 is softened, but the crystallization of the inner surface of the crucible advances uniformly, and thus the strength of the crucible can be secured and deformation can be suppressed. Therefore, it is possible to prevent the contact with the member in the furnace due to the deformation of the crucible or the fluctuation of the melt surface position of the silicon melt 3 due to the change in the volume of the crucible.

As described above, the quartz glass crucible 1 according to the present embodiment includes the crucible base body 10 consisting of silica glass and the crystallization accelerator-containing coating film 13 formed on the inner surface 10i of the crucible base body 10, in which the concentration of Al in the depth region D1 from the inner surface 10i of the crucible base body 10 to at least 0.5 mm is lower than the concentration of Fe or Ca in the depth region D1, and the crystallization rate in the in-plane direction when the inner surface is crystallized at a high temperature in the crystal pulling up step is higher than the crystallization rate in the depth direction. Therefore, even in a case where the coating unevenness of the crystallization accelerator occurs on the inner surface 10i, the inner surface of the crucible can be finally covered with a uniform crystal plane, and the peeling of the crystal grains can be prevented.

Although preferred embodiments of the present invention were described above, the present invention is not limited to the above-described embodiments, and various modifications can be added without departing from the scope of the present invention, and such modifications are, needless to say, covered by the scope of the present invention.

### EXAMPLES

Four crucible base bodies having different concentrations of metal impurities on an inner surface were prepared, a part of the inner surface of the crucible base body was coated with a barium carbonate solution with a brush, and then the crucible was crushed and fragmented. Among a plurality of crucible pieces obtained from the same crucible base body, those not coated with barium carbonate were used to perform the metal impurity analysis in the depth direction from the inner surface of the crucible base body. In the metal impurity analysis, silica glass at a certain depth from the inner surface of the crucible was dissolved by wet etching, the etchant was recovered, and the amount of metal impurities dissolved in the etchant was measured by inductively coupled plasma-mass spectrometry (ICP-MS).

In the measurement of Fe, Ca, and Al among the metal impurities, a depth region from the inner surface of the crucible base body to 0.3 mm was set as a measurement range of the first measurement, a depth region of 0.3 to 0.5 mm from the inner surface of the crucible base body was set as a measurement range of the second measurement, and a depth region of 0.5 to 0.7 mm from the inner surface of the crucible base body was set as a measurement range of the third measurement. The measurement results are shown in Table 1 and Table 2.

TABLE 1

| | Impurity concentration profile in a depth | | | | | | | |
|---|---|---|---|---|---|---|---|---|
| | direction from an inner surface (ppm) | | | | | | Ratio of | |
| | 0 to 0.3 mm | | 0.3 to 0.5 mm | | 0.5 to 0.7 mm | | crystallization rate | Crystallization |
| | Fe | Al | Fe | Al | Fe | Al | (in-plane/depth) | unevenness |
| Comparative | 0.02 | 0.03 | 0.02 | 0.03 | 0.02 | 0.03 | 0.5 | Present |
| Example 1 | | | | | | | | |
| Comparative | 0.06 | 0.03 | 0.02 | 0.03 | 0.02 | 0.03 | 1 | Present |
| Example 2 | | | | | | | | |
| Example 1 | 0.1 | 0.03 | 0.05 | 0.03 | 0.02 | 0.03 | 1.5 | Absent |
| Example 2 | 0.2 | 0.03 | 0.1 | 0.03 | 0.05 | 0.03 | 100 | Absent |

As shown in Table 1, in the Fe and Al concentration profiles of the crucible base body of Comparative Example 1, the Fe concentration was low in the entire region from the inner surface to 0.7 mm in the depth direction, and a relationship of Fe concentration<Al concentration was established. In addition, in the Fe and Al concentration profiles of the crucible base body of Comparative Example 2, a relationship of Fe concentration>Al concentration was established in a depth region from the inner surface to 0.3 mm, and a relationship of Fe concentration<Al concentration was established in a depth region of 0.3 to 0.7 mm. On the other hand, in the Fe and Al concentration profiles of the crucible base body of Example 1, a relationship of Fe concentration>Al concentration was established in a depth region from the inner surface to 0.5 mm, and a relationship of Fe concentration<Al concentration was established in a depth region of 0.5 to 0.7 mm. Furthermore, in the crucible base body of Example 2, a relationship of Fe concentration>Al concentration was established in the entire region of the depth direction from the inner surface to 0.7 mm.

TABLE 2

| | Impurity concentration profile in a depth | | | | | | | |
|---|---|---|---|---|---|---|---|---|
| | direction from an inner surface (ppm) | | | | | | Ratio of | |
| | 0 to 0.3 mm | | 0.3 to 0.5 mm | | 0.5 to 0.7 mm | | crystallization rate | Crystallization |
| | Ca | Al | Ca | Al | Ca | Al | (in-plane/depth) | unevenness |
| Comparative | 0.02 | 0.03 | 0.02 | 0.03 | 0.02 | 0.03 | 0.5 | Present |
| Example 1 | | | | | | | | |
| Comparative | 0.2 | 0.03 | 0.02 | 0.03 | 0.02 | 0.03 | 1 | Present |
| Example 2 | | | | | | | | |
| Example 1 | 0.4 | 0.03 | 0.2 | 0.03 | 0.02 | 0.03 | 1.5 | Absent |
| Example 2 | 0.5 | 0.03 | 0.4 | 0.03 | 0.2 | 0.03 | 100 | Absent |

As shown in Table 2, the Ca concentration profile also had the same tendency as Fe concentration profile. That is, in the Ca and Al concentration profiles of the crucible base body of Comparative Example 1, the Ca concentration was low in the entire region from the inner surface to 0.7 mm in the depth direction, and the relationship of Ca concentration<Al concentration was established. In addition, in the Ca and Al concentration profiles of the crucible base body of Comparative Example 2, a relationship of Ca concentration>Al concentration was established in a depth region from an inner surface to 0.3 mm, and a relationship of Ca concentration<Al concentration was established in a depth region of 0.3 to 0.7 mm. On the other hand, in the Ca and Al concentration profiles of the crucible base body of Example 1, a relationship of Ca concentration>Al concentration was established in a depth region from the inner surface to 0.5 mm, and a relationship of Ca concentration<Al concentration was established in a depth region of 0.5 to 0.7 mm. Furthermore, in the crucible base body of Example 2, a relationship of Ca concentration>Al concentration was established in the entire region of the depth direction from the inner surface to 0.7 mm.

As described above, in the crucible samples of Comparative Examples 1 and 2, the Fe concentration and the Ca concentration in the depth region from the inner surface to 0.5 mm were lower than the Al concentration, whereas in the crucible samples of Examples 1 and 2, the Al concentration in the depth region from the inner surface to 0.5 mm was lower than the Fe concentration and the Ca concentration.

In the measurement of B, Mg, and Cr among the metal impurities, the depth region from the inner surface to 1.0 mm was set as a measurement range of the first measurement, the depth region of 1.0 to 2.0 mm was set as a measurement range of the second measurement, the depth region of 2.0 to 3.0 mm was set as a measurement range of the third measurement, the depth region of 3.0 to 4.0 mm was set as a measurement range of the fourth measurement, and the depth region of 4.0 to 5.0 mm was set as a measurement range of the fifth measurement. The measurement results are shown in Table 3 to Table 5.

TABLE 3

| | B concentration profile in a depth | | | | | Ratio of | |
|---|---|---|---|---|---|---|---|
| | direction from an inner surface (ppm) | | | | | crystallization rate | Crystallization |
| | 0 to 1 mm | 1 to 2 mm | 2 to 3 mm | 3 to 4 mm | 4 to 5 mm | (in-plane/depth) | unevenness |
| Comparative | 0.1 | 0.1 | 0.1 | 0.1 | 0.1 | 0.5 | Present |
| Example 1 | | | | | | | |
| Comparative | 0.01 | 0.1 | 0.1 | 0.1 | 0.1 | 1 | Present |
| Example 2 | | | | | | | |
| Example 1 | 0.01 | 0.02 | 0.1 | 0.1 | 0.1 | 1.5 | Absent |
| Example 2 | 0.01 | 0.02 | 0.02 | 0.1 | 0.1 | 100 | Absent |

As shown in Table 3, in the B concentration profile of the crucible base body of Comparative Example 1, the B concentration was 0.1 ppm in the entire region of 5 mm or less from the inner surface in the depth direction. In the B concentration profile of the crucible base body of Comparative Example 2, the B concentration within a depth region of 1 mm from the inner surface was 0.01 ppm, but the B concentration profile within a depth region of 1 to 5 mm was 0.1 ppm. In the B concentration profile of the crucible base body of Example 1, the B concentration within a depth region of 2 mm from the inner surface was 0.02 ppm, but the B concentration profile within a depth region of 2 to 5 mm was 0.1 ppm. In the B concentration profile of the crucible base body of Example 2, the B concentration within a depth region of 3 mm from the inner surface was 0.02 ppm, but the B concentration profile within a depth region of 3 to 5 mm was 0.1 ppm.

TABLE 4

| | Mg concentration profile in a depth | | | | | Ratio of | |
|---|---|---|---|---|---|---|---|
| | direction from an inner surface (ppm) | | | | | crystallization rate | Crystallization |
| | 0 to 1 mm | 1 to 2 mm | 2 to 3 mm | 3 to 4 mm | 4 to 5 mm | (in-plane/depth) | unevenness |
| Comparative | 0.14 | 0.14 | 0.14 | 0.14 | 0.14 | 0.5 | Present |
| Example 1 | | | | | | | |
| Comparative | 0.01 | 0.14 | 0.14 | 0.14 | 0.14 | 1 | Present |
| Example 2 | | | | | | | |
| Example 1 | 0.01 | 0.01 | 0.14 | 0.14 | 0.14 | 1.5 | Absent |
| Example 2 | 0.01 | 0.01 | 0.01 | 0.14 | 0.14 | 100 | Absent |

As shown in Table 4, in the Mg concentration profile of the crucible base body of Comparative Example 1, the Mg concentration was 0.14 ppm in the entire region of 5 mm or less from the inner surface in the depth direction. In the Mg concentration profile of the crucible base body of Comparative Example 2, the Mg concentration within a depth region of 1 mm from the inner surface was 0.01 ppm, but the Mg concentration profile within a depth region of 1 to 5 mm was 0.14 ppm. In the Mg concentration profile of the crucible base body of Example 1, the Mg concentration within a depth region of 2 mm from the inner surface was 0.01 ppm or less, but the Mg concentration profile within a depth region of 2 to 5 mm was 0.14 ppm. In the Mg concentration profile of the crucible base body of Example 2, the Mg concentration within a depth region of 3 mm from the inner surface was 0.01 ppm or less, but the Mg concentration profile within a depth region of 3 to 5 mm was 0.14 ppm.

TABLE 5

| | Cr concentration profile in a depth | | | | | Ratio of | |
|---|---|---|---|---|---|---|---|
| | direction from an inner surface (ppm) | | | | | crystallization rate | Crystallization |
| | 0 to 1 mm | 1 to 2 mm | 2 to 3 mm | 3 to 4 mm | 4 to 5 mm | (in-plane/depth) | unevenness |
| Comparative | 0.08 | 0.08 | 0.08 | 0.08 | 0.08 | 0.5 | Present |
| Example 1 | | | | | | | |
| Comparative | 0.01 | 0.08 | 0.08 | 0.08 | 0.08 | 1 | Present |
| Example 2 | | | | | | | |
| Example 1 | 0.01 | 0.02 | 0.08 | 0.08 | 0.08 | 1.5 | Absent |
| Example 2 | 0.01 | 0.02 | 0.02 | 0.08 | 0.08 | 100 | Absent |

As shown in Table 5, in the Cr concentration profile of the crucible base body of Comparative Example 1, the Cr concentration was 0.08 ppm in the entire region of 5 mm or less from the inner surface in the depth direction. In the Cr concentration profile of the crucible base body of Comparative Example 2, the Cr concentration within a depth region of 1 mm from the inner surface was 0.01 ppm, but the Cr concentration profile within a depth region of 1 to 5 mm was 0.08 ppm. In the Cr concentration profile of the crucible base body of Example 1, the Cr concentration within a depth region of 2 mm from the inner surface was 0.02 ppm or less, but the Cr concentration profile within a depth region of 2 to 5 mm was 0.08 ppm. In the Cr concentration profile of the crucible base body of Example 2, the Cr concentration within a depth region of 3 mm from the inner surface was 0.02 ppm or less, but the Cr concentration profile within a depth region of 3 to 5 mm was 0.08 ppm.

As described above, in the crucible samples of Comparative Examples 1 and 2, the maximum value of the B concentration in the depth region from the inner surface to 2.0 mm was equal to the maximum value of the B concentration in the depth region of 2.0 to 5.0 mm from the inner surface, whereas in the crucible samples of Examples 1 and 2, the maximum value of the B concentration in the depth region from the inner surface to 2.0 mm or less was lower than the maximum value of the B concentration in the depth region of 2.0 to 5.0 mm from the inner surface. The same tendency was observed in Mg and Cr.

Next, a heating test was performed using the crucible piece coated with barium carbonate. In the heating test, a crucible piece having one side of 10 to 20 cm and an area of 200 cm² or more and having an aspect ratio as close to 1 as possible was used. As heating conditions, the temperature of the furnace in an Ar atmosphere was raised from room temperature to 1,580° C. over 2.5 hours, and then 1,580° C. was held for 10 hours. The pressure in the furnace held at 1,580° C. was set to 20 Torr.

Thereafter, the crystallization state of the inner surface of the crucible base body was evaluated. Specifically, the crystallization rate in the in-plane direction and the crystallization rate in the depth direction were each determined from the width and the thickness of the crystal layer on the inner surface of the crucible base body, and furthermore, the presence or absence of crystallization unevenness was visually confirmed. Here, the crystallization rate in the in-plane direction is a value obtained by dividing the length of the crystallization in the in-plane direction by 10 hours, which is the time during which the temperature is held at a high temperature of 1,580° C. Similarly, the crystallization rate in the depth direction is a value obtained by dividing the length of the crystallization in the depth direction by 10 hours. The length in the in-plane direction of crystallization is the maximum distance indicating the spread of the crystal layer from the starting point of crystallization. In addition, the length in the depth direction of crystallization is the maximum thickness of the crystal layer in a cross section of the sample cut. The crystallization unevenness refers to a state in which there is a portion in which the inner surface of the crucible base body loses transparency and remains glassy in the coating range of the barium carbonate, and particularly refers to a state in which 5% or more of the area loses transparency.

As a result, as shown in Tables 1 to 5, crystallization unevenness was observed on the inner surface in the crucible samples of Comparative Examples 1 and 2, but crystallization unevenness was not observed on the inner surface and the entire surface was uniformly crystallized in the crucible samples of Examples 1 and 2. In a case where a ratio of the crystallization rate in the in-plane direction to the crystallization rate in the depth direction of each crucible sample was calculated, the ratio was 0.5 in Comparative Example 1, 1 in Comparative Example 2, 1.5 in Example 1, and 100 in Example 2. From the above results, it was found that, in a case where the ratio of the crystallization rate is 1.5 or more, the inner surface of the crucible can be crystallized without unevenness.

### DESCRIPTION OF REFERENCE NUMERALS

1 Quartz glass crucible
2 Silicon single crystal
3 Silicon melt
10 Crucible base body
10a Sidewall
10b Bottom
10c Corner
10i Inner surface
11 Transparent layer
12 Bubble layer
13 Crystallization accelerator-containing coating film
14 Carbon mold
14a Vent hole
14i Inner surface of carbon mold
15 Arc electrode
16: Deposited layer of raw material quartz particles
16a Natural quartz particles
16b Synthetic quartz particles
20 Single crystal pulling apparatus
21 Chamber
21a Main chamber
21b Pull chamber
21c Gas entry
21d Gas outlet
22 Carbon susceptor
23 Rotating shaft
24 Shaft driving mechanism
25 Heater
28 Wire for pulling up single crystal
29 Wire winding mechanism

1. A quartz glass crucible for pulling up a silicon single crystal, comprising:
a crucible base body consisting of silica glass; and
a crystallization accelerator-containing coating film formed on an inner surface of the crucible base body,
wherein a concentration of Fe contained in a first depth region of the crystallization accelerator-containing coating film of 0.5 mm or less from the inner surface is higher than a concentration of Al contained in the first depth region of the crystallization accelerator-containing coating film.

2. The quartz glass crucible according to claim 1,
wherein a concentration of Ca contained in the first depth region of the crystallization accelerator-containing coating film is higher than the concentration of Al contained in the first depth region of the crystallization accelerator-containing coating film.

3. The quartz glass crucible according to claim 1,
wherein a concentration of B contained in a second depth region of the crystallization accelerator-containing coating film of 2 mm or less from the inner surface is lower than a concentration of B contained in a third depth region of the crystallization accelerator-containing coating film of 2 mm or more and 5 mm or less from the inner surface.

4. The quartz glass crucible according to claim 3,
wherein a concentration of Mg contained in the second depth region of the crystallization accelerator-containing coating film is lower than a concentration of Mg contained in the third depth region of the crystallization accelerator-containing coating film.

5. The quartz glass crucible according to claim 3,
wherein a concentration of Cr contained in the second depth region of the crystallization accelerator-containing coating film is lower than a concentration of Cr contained in the third depth region of the crystallization accelerator-containing coating film.

6. The quartz glass crucible according to claim 1,
wherein a concentration of a crystallization accelerator in the crystallization accelerator-containing coating film is 1.0×10¹² to 2.6×10¹⁵ atoms/cm².

7. The quartz glass crucible according to claim 1,
wherein a ratio of a crystallization rate of the inner surface in an in-plane direction of the inner surface to a crystallization rate in a depth direction of the inner surface is 1.5 to 400 in a case where a heat treatment is performed on the quartz glass crucible at 1,580° C.

8. The quartz glass crucible according to claim 7,
wherein, in the heat treatment, a temperature rising time from room temperature to 1,580° C. is 2.5 hours, a holding time at 1,580° C. is 10 hours, and an atmospheric pressure during the heat treatment is 20 Torr.

9. The quartz glass crucible according to claim 8,
wherein a length of crystallization that spreads on the inner surface after the heat treatment is 1 mm to 60 mm in an in-plane direction.

10. The quartz glass crucible according to claim 7,
wherein a crystallization accelerator contained in the crystallization accelerator-containing coating film is Ba, and a concentration of Ba in a crystal layer formed after the heat treatment is less than 1 ppm.

11. The quartz glass crucible according to claim 1,
wherein the crucible base body has a cylindrical sidewall, a bottom, and a corner provided between the sidewall and the bottom,
a rim vicinity region from an upper end of a rim to at least 20 mm downward from the rim on the inner surface of the crucible base body, is a crystallization accelerator uncoated region, and
the crystallization accelerator-containing coating film is formed on the entire inner surface excluding the uncoated region.

12. A manufacturing method of a silicon single crystal, comprising:
pulling up a silicon single crystal using the quartz glass crucible according to claim 1.

13. A manufacturing method of a silicon single crystal, comprising:
pulling up a silicon single crystal using the quartz glass crucible according to claim 2.

14. A manufacturing method of a silicon single crystal, comprising:
pulling up a silicon single crystal using the quartz glass crucible according to claim 3.

15. A manufacturing method of a silicon single crystal, comprising:
pulling up a silicon single crystal using the quartz glass crucible according to claim 4.

16. A manufacturing method of a silicon single crystal, comprising:
pulling up a silicon single crystal using the quartz glass crucible according to claim 5.

17. A manufacturing method of a silicon single crystal, comprising:
pulling up a silicon single crystal using the quartz glass crucible according to claim 6.

18. A manufacturing method of a silicon single crystal, comprising:
pulling up a silicon single crystal using the quartz glass crucible according to claim 7.

19. A manufacturing method of a silicon single crystal, comprising:
pulling up a silicon single crystal using the quartz glass crucible according to claim 8.

20. A manufacturing method of a silicon single crystal, comprising:
pulling up a silicon single crystal using the quartz glass crucible according to claim 9.

21. A manufacturing method of a silicon single crystal, comprising:
pulling up a silicon single crystal using the quartz glass crucible according to claim 10.

22. A manufacturing method of a silicon single crystal, comprising:
pulling up a silicon single crystal using the quartz glass crucible according to claim 11.
